(19) United States
(12) Patent Application Publication
(10) Pub. No.: US 2006/0131600 A1
(43) Pub. Date: Jun. 22, 2006

(54) Light transmitting window member, semiconductor package provided with light transmitting window member and method for manufacturing light transmitting window member

(76) Inventors: Junichi Nakaoka, Izumi-shi (JP); Kenji Ikeuchi, Kyoto-shi (JP); Makoto Takahashi, Toyonaka-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(21) Appl. No.: 10/548,224

(22) PCT Filed: Mar. 2, 2005
(86) PCT No.: PCT/JP05/03457

§ 371 Date: Sep. 2, 2005

(30) Foreign Application Priority Data
Mar. 6, 2004 (JP) 2004-061567

(51) Int. Cl. H01L 33/00

(52) U.S. Cl. 257/99; 257/434; 257/E33.058

(57) ABSTRACT

A light transmission window member capable of simplifying the structure and capable of simplifying manufacturing steps is obtained. This light transmission window member (10, 10a), which is a light transmission window member employed for a semiconductor package (30, 30a), comprises a flat metal frame (2) having an opening (2a) for defining a light passage region and a glass member (1) capable of transmitting light bonded to the upper surface of the flat frame having the opening without through an adhesive to cover the opening.

### TECHNICAL FIELD

The present invention relates to a light transmission window member, a semiconductor package comprising a light transmission window member and a method of manufacturing a light transmission window member, and more particularly, it relates to a light transmission window member including a glass member capable of transmitting light, a semiconductor package comprising a light transmission window member and a method of manufacturing a light transmission window member.

### BACKGROUND TECHNIQUE

Various light transmission window members including glass members capable of transmitting light employed for semiconductor packages are known in general. For example, Japanese Patent Laying-Open No. 9-148469 discloses this type of light transmission window member.

The aforementioned Japanese Patent Laying-Open No. 9-148469 discloses a light transmission window member having a structure obtained by forming an opening (opening region) for defining a light passage region on a glass member (glass window) by metal plating or the like and bonding the gold-plated portion of the glass member provided with the opening to a metal frame provided with an opening for transmitting light through a solder layer.

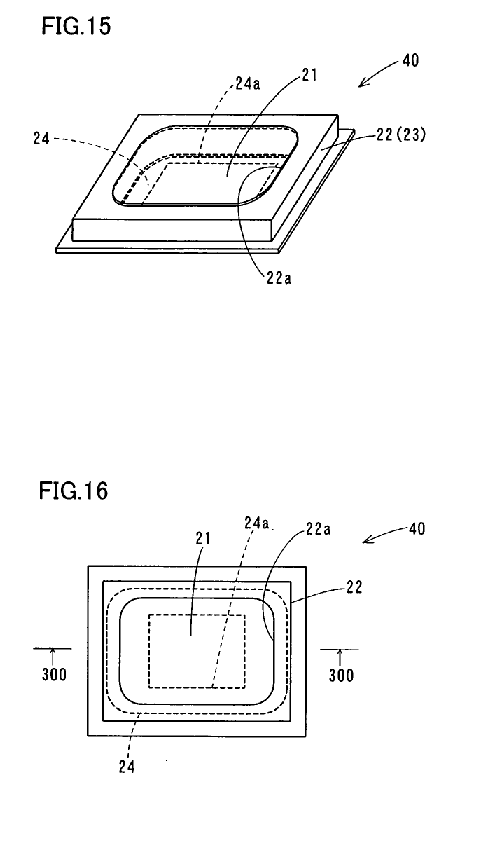

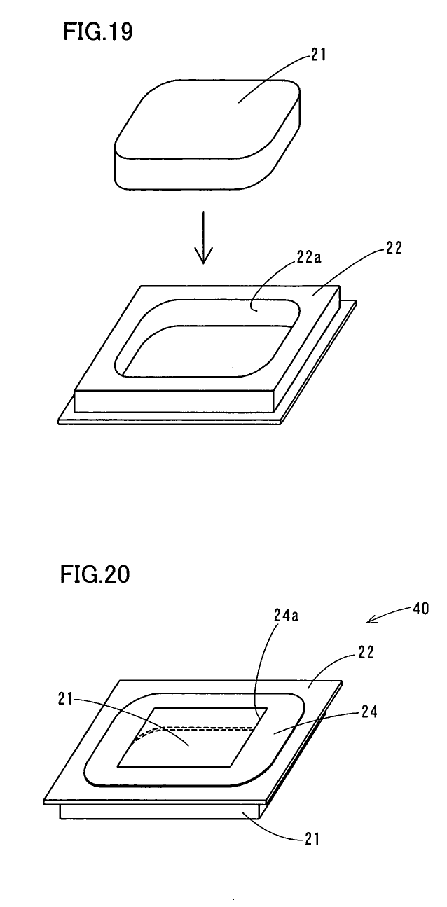

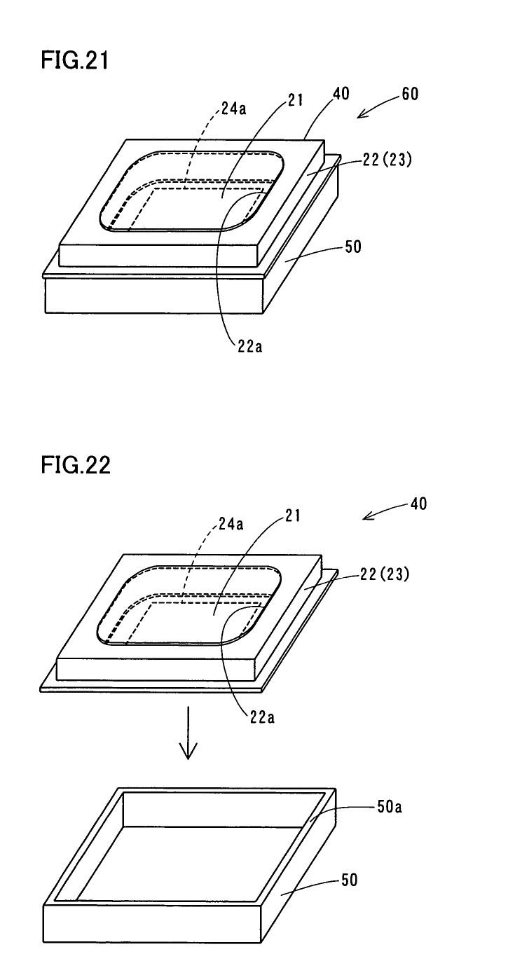

A light transmission window member having a structure obtained by welding the outer side surface of a glass member and the inner side surface of a metal frame to each other while fitting the glass member in an opening of the frame is also known in general. FIGS. 15 to 18 are diagrams showing the overall structure of a conventional light transmission window member having such a structure. FIGS. 19 and 20 are perspective views for illustrating manufacturing steps for the conventional light transmission window member shown in FIG. 15. FIG. 21 is a perspective view showing the overall structure of a semiconductor package comprising the light transmission window member shown in FIG. 15. FIG. 22 is a perspective view for illustrating a manufacturing step for the semiconductor package comprising the light transmission window member shown in FIG. 15. The structures of the conventional light transmission window member and the semiconductor package comprising the light transmission window member are first described with reference to FIGS. 15 to 18 and 21.

The conventional light transmission window member 40 comprises a glass member 21 capable of transmitting light, a metal frame 22, a gold plating layer 23 and a chromium evaporation layer 24, as shown in FIGS. 15 to 18. The glass member 21 is fitted in an opening 22a of the frame 22. In this state, the outer side surface of the glass member 21 and the inner side surface of the opening 22a of the frame 22 are bonded to each other by glass welding. The frame 22 includes an outer peripheral portion having a small thickness (about 0.2 mm) and an inner side portion, located inside the outer peripheral portion, having a larger thickness (about 3 mm) than the outer peripheral portion. The thickness of the inner side portion of the frame 22 is set to a value slightly smaller than the thickness of the glass member 21, so that the bond length (bond margin) of the region bonded to the glass member 21 can be set somewhat large and the surface of the glass member 21 can be projected slightly beyond the surface of the frame 22 and easily polished after the glass member 21 and the frame 22 are bonded to each other. The gold plating layer 23 is formed to cover the outer surface of the frame 22. The chromium evaporation layer 24 is formed to extend over part of the gold plating layer 23 on the lower surface of the frame 22 and part of the lower surface of the glass member 21. The chromium evaporation layer 24 is formed with an opening region 24a for defining a light entrance region. The conventional light transmission window member 40 is bonded to a metal housing 50 storing a DMD element (Digital Micromirror Device) (not shown) serving as a display device used for a projector, for example, as shown in FIG. 21. This light transmission window member 40 and the housing 50 constitute a conventional semiconductor package 60.

A method of manufacturing the conventional light transmission window member 40 is now described with reference to FIGS. 15, 19 and 20. First, the metal frame 22 having the outer peripheral portion of the small thickness and including the inner side portion of the large thickness having the opening 22a is formed as shown in FIG. 19. In other words, the outer peripheral portion of the frame 22 having the small thickness is formed by cutting, while the opening 22a of the frame 22 is formed by press working. The glass member 21 is inserted into the opening 22a of the frame 22. Thereafter the outer side surface of the glass member 21 is welded to the inner side surface of the opening 22a of the frame 22 by entirely heating the glass member 21 and the frame 22 to a temperature exceeding the softening point (about 800° C.) of the glass member 21. Thereafter the gold plating layer 23 is formed by electrolytic plating to cover the overall outer surface of the frame 22. In the aforementioned welding, the glass member 21 softens to reduce flatness and parallelism of the glass member 21. In general, therefore, the flatness and the parallelism of the surface of the glass member 21 are improved by polishing the upper surface and the lower surface of the glass member 21 after formation of the gold plating layer 23 after welding the glass member 21 to the frame 22. After the upper surface and the lower surface of the glass member 21 are thus polished, the chromium evaporation layer 24 is formed to cover part of the gold plating layer 23 for the frame 22 and part of the lower surface of the glass member 21 while forming the opening region 24a for defining a light entrance region by vacuum evaporation, as shown in FIG. 20. The conventional light transmission window member 40 shown in FIG. 15 is formed in this manner.

As shown in FIG. 22, the lower surface of the small-thickness outer peripheral portion of the frame 22 of the light transmission window member 40 formed in the aforementioned manner is bonded to the upper surface 50a of the outer peripheral portion of the housing 50, to close the housing 50. Thus, the semiconductor package 60 comprising the conventional light transmission window member 40 is formed.

In the conventional light transmission window member 40 shown in FIGS. 15 to 18, however, the outer side surface of the glass member 21 and the inner side surface of the opening 22a of the frame 22 are welded to each other, and hence it is necessary to increase the thickness of the inner side portion of the frame 22 to an extent equivalent to the thickness of the glass member 21 in order to increase the bond length (bond margin) of the glass member 21 and the frame 22 to some extent for holding bond strength. On that account, there is such a problem that the material cost for the frame 22 is increased as compared with a case where the thickness of the frame 22 is small and it is difficult to simplify the structure of the light transmission window member 40 due to the large thickness of the frame 22. In the conventional light transmission window member 40, further, the opening region 24a for defining the light passage region must also be provided on the lower surface of the glass member 21 in addition to the provision of the opening 22a on the frame 22, and hence it has been difficult to simplify the structure and the manufacturing steps.

In the structure disclosed in the aforementioned Japanese Patent Laying-Open No. 9-148469, the opening region (opening) for defining the light passage region is provided also on the glass member in addition to the provision of the opening on the frame, and hence there is such a problem that it is difficult to simplify the structure and manufacturing steps similarly to the conventional light transmission window member 40 shown in FIGS. 15 to 18.

### DISCLOSURE OF THE INVENTION

The present invention has been proposed in order to solve the aforementioned problems, and an object of the present invention is to provide a light transmission window member capable of simplifying the structure and capable of simplifying manufacturing steps, a semiconductor package comprising a light transmission window member and a method of manufacturing a light transmission window member.

In order to attain the aforementioned object, a light transmission window member according to a first aspect of the present invention, which is a light transmission window member employed for a semiconductor package, comprises a flat metal frame having an opening for defining a light passage region and a glass member capable of transmitting light bonded to the upper surface of the flat frame having the opening without through an adhesive to cover the opening.

In the light transmission window member according to the first aspect of the present invention, as hereinabove described, the glass member capable of transmitting light is bonded to the upper surface of the flat metal frame having the opening for defining the light passage region without through an adhesive to cover the opening, whereby the thickness of the frame may not be increased and no opening region for defining a light entrance region may be provided on the side of the glass member separately from the opening of the frame dissimilarly to a case of bonding the glass member to the inner side surface of the opening of the frame. Thus, the thickness of the frame can be reduced, and the structure of the light transmission window member can be simplified. Further, no opening region for defining a light entrance region may be provided on the side of the glass member separately from the opening of the frame, whereby there is no need for a step of evaporating a shielding film of chromium or the like necessary in a case of providing an opening region on the glass member. Consequently, manufacturing steps for the light transmission window member can be simplified.

In the aforementioned light transmission window member according to the first aspect, the flat metal frame having the opening defining the light transmission region and the glass member are preferably bonded to each other through an Al layer. According to this structure, part (γ-alumina) of Al can be formed to extend in a comblike manner in the interface of the glass member when bonding the frame and the glass member to each other through the Al layer by anodic bonding, for example, whereby the bond strength between the Al layer and the glass member can be increased. Thus, the bond strength between the metal frame and the glass member can be increased.

In the aforementioned light transmission window member according to the first aspect, the glass member is preferably anodically bonded to the upper surface of the flat frame having the opening defining the light transmission region. When employing anodic bonding in this manner, the bonding temperature for the upper surface of the flat frame and the glass member can be reduced below the softening point of the glass member, whereby the surface of the glass member is inhibited from softening by the temperature for bonding the flat frame and the glass member to each other. Thus, the flatness and the parallelism of the glass member can be inhibited from reduction, whereby the surface of the glass member may not be polished after the bonding between the upper surface of the flat frame and the glass member. Consequently, polishing can be performed in the single state of the glass member before the bonding between the glass member and the frame, whereby the glass member can be more easily polished as compared with a case of polishing the glass member bonded to the frame after the bonding between the glass member and the frame. Thus, the polishing step for the glass member can be simplified.

In the aforementioned light transmission window member according to the first aspect, the glass member is preferably bonded to the upper surface of the flat frame having the opening defining the light transmission region at a temperature of not more than the softening point of the glass member. According to this structure, the surface of the glass member is easily inhibited from softening by the temperature for bonding the flat frame and the glass member to each other. Thus, the flatness and the parallelism of the glass member can be easily inhibited from reduction, whereby the surface of the glass member may not be polished after the bonding between the upper surface of the flat frame and the glass member. Consequently, polishing can be performed in the single state of the glass member before the bonding between the glass member and the frame, whereby the glass member can be more easily polished as compared with a case of polishing the glass member bonded to the frame after the bonding between the glass member and the frame. Thus, the polishing step for the glass member can be simplified.

In the aforementioned light transmission window member according to the first aspect, the upper surface of the flat frame having the opening defining the light transmission region, to which the glass member is bonded, is preferably mirror-finished. According to this structure, formation of a clearance between the bonded surfaces of the upper surface of the flat frame and the glass member is suppressed, whereby air can be inhibited from passing through the bonded surfaces of the upper surface of the flat frame and the glass member. Thus, when bonding the light transmission window member having the frame and the glass member bonded to each other to a housing of the semiconductor package, the housing can be held in a closed state with the light transmission window member.

In the aforementioned light transmission window member according to the first aspect, the metal frame having the opening defining the light transmission region preferably has a thermal expansion coefficient in the vicinity of the thermal expansion coefficient of the glass member. According to this structure, the glass member can be inhibited from warping or distortion resulting from difference between the thermal expansion coefficients of the metal frame and the glass member when the temperatures of the metal frame and the glass member lower to the ordinary temperature after the bonding.

In the aforementioned light transmission window member provided with the metal frame having the thermal expansion coefficient in the vicinity of the thermal expansion coefficient of the glass member, the frame having the opening defining the light transmission region preferably consists of an iron-nickel-cobalt alloy. According to this structure, the thermal expansion coefficient of the frame can be easily approximated to the thermal expansion coefficient of the glass member with the frame of KOVAR (Registered Trademark) (iron-nickel-cobalt alloy (29Ni-16Co—Fe, for example)), for example.

In the aforementioned light transmission window member according to the first aspect, the glass member preferably contains alkaline ions. According to this structure, the frame and the glass member can be easily anodically bonded to each other when bonding the frame and the glass member to each other by anodic bonding, for example.

In the aforementioned light transmission window member according to the first aspect, the lower surface of the metal frame is preferably bonded to a metal housing of the semiconductor package to close the housing. According to this structure, the housing can be easily closed with the light transmission window member formed by bonding the metal frame having the opening for defining the light passage region and the glass member to each other.

In the aforementioned light transmission window member according to the first aspect, the lower surface of the metal frame is preferably bonded to the metal housing of the semiconductor package by resistance welding. According to this structure, the lower surface of the metal frame and the housing can be bonded to each other by heating only the bonded portions. Thus, the temperature of the glass member can be reduced below the softening point of the glass member when bonding the metal frame and the housing to each other, whereby the surface of the glass member is inhibited from softening by the temperature for bonding the metal frame and the housing to each other. Thus, the flatness and the parallelism of the glass member can be inhibited from reduction, whereby the light transmission properties of the glass member can be inhibited from reduction. Further, the temperature of a semiconductor device stored in the housing can be inhibited from increase when bonding the metal frame and the housing to each other, whereby the semiconductor device stored in the housing can be prevented from breakage resulting from temperature rise in the bonding between the metal frame and the housing.

A semiconductor package according to a second aspect of the present invention comprises a light transmission window member including a flat metal frame having an opening for defining a light passage region and a glass member capable of transmitting light bonded to the upper surface of the flat frame having the opening without through an adhesive to cover the opening.

In the semiconductor package according to the second aspect of the present invention, as hereinabove described, the glass member capable of transmitting light is bonded to the upper surface of the flat metal frame having the opening for defining the light passage region without through an adhesive to cover the opening, whereby the thickness of the frame may not be increased and no opening region for defining a light entrance region may be provided on the side of the glass member separately from the opening of the frame dissimilarly to a case of bonding the glass member to the inner side surface of the opening of the frame. Thus, the thickness of the frame can be reduced, and the structure of the light transmission window member can be simplified. Further, no opening region for defining a light entrance region may be provided on the side of the glass member separately from the opening of the frame, whereby there is no need for a step of evaporating a shielding film of chromium or the like necessary in a case of providing an opening region on the glass member. Consequently, manufacturing steps for the light transmission window member can be simplified.

In the aforementioned semiconductor package according to the second aspect, the flat metal frame having the opening defining the light transmission region and the glass member are preferably bonded to each other through an Al layer. According to this structure, part (γ-alumina) of Al can be formed to extend in a comblike manner in the interface of the glass member when bonding the frame and the glass member to each other through the Al layer by anodic bonding, for example, whereby the bond strength between the Al layer and the glass member can be increased. Thus, the bond strength between the metal frame and the glass member can be increased.

In the aforementioned semiconductor package according to the second aspect, the glass member is preferably anodically bonded to the upper surface of the flat frame. When employing anodic bonding in this manner, the bonding temperature for the upper surface of the flat frame and the glass member can be reduced below the softening point of the glass member, whereby the surface of the glass member is inhibited from softening by the temperature for bonding the flat frame and the glass member to each other. Thus, the flatness and the parallelism of the glass member can be inhibited from reduction, whereby the surface of the glass member may not be polished after the bonding between the upper surface of the flat frame and the glass member. Consequently, polishing can be performed in the single state of the glass member before the bonding between the glass member and the frame, whereby the glass member can be more easily polished as compared with a case of polishing the glass member bonded to the frame after the bonding between the glass member and the frame. Thus, the polishing step for the glass member can be simplified.

In the aforementioned semiconductor package according to the second aspect, the glass member is preferably bonded to the upper surface of the flat frame having the opening defining the light transmission region at a temperature of not more than the softening point of the glass member. According to this structure, the surface of the glass member is easily inhibited from softening by the temperature for bonding the flat frame and the glass member to each other. Thus, the flatness and the parallelism of the glass member can be easily inhibited from reduction, whereby the surface of the glass member may not be polished after the bonding between the upper surface of the flat frame and the glass member. Consequently, polishing can be performed in the single state of the glass member before the bonding between the glass member and the frame, whereby the glass member can be more easily polished as compared with a case of polishing the glass member bonded to the frame after the bonding between the glass member and the frame. Thus, the polishing step for the glass member can be simplified.

The aforementioned semiconductor package according to the second aspect preferably further comprises a housing bonded to the lower surface of the metal frame to be closed by the lower surface of the metal frame for storing a semiconductor device. According to this structure, the housing can be easily closed with the light transmission window member formed by bonding the metal frame having the opening for defining the light passage region and the glass member to each other.

In the aforementioned semiconductor package comprising the housing storing the semiconductor device, the metal frame and the housing preferably consist of the same material. According to this structure, the thermal expansion coefficients of the metal frame and the housing can be rendered identical to each other, whereby the frame can be inhibited from warping or distortion resulting from difference between the thermal expansion coefficients of the metal frame and the housing when the temperatures of the metal frame and the housing lower to the ordinary temperature after the bonding. Thus, the glass member bonded to the upper surface of the frame can be inhibited from warping or distortion.

In the aforementioned semiconductor package having the metal frame and the housing consisting of the same material, the metal frame and the housing preferably consist of an iron-nickel-cobalt alloy. According to this structure, the thermal expansion coefficients of the frame and the housing can be easily approximated to the thermal expansion coefficient of the glass member with the frame and the housing of KOVAR (iron-nickel-cobalt alloy (29Ni-16Co—Fe, for example)), for example. Thus, when the temperatures of the metal frame, the housing and the glass member lower to the ordinary temperature after the bonding, the glass member can be inhibited from warping or distortion resulting from difference between the thermal expansion coefficients of the metal frame, the housing and the glass member.

In the aforementioned semiconductor package comprising the housing storing the semiconductor device, the lower surface of the metal frame is preferably bonded to the metal housing of the semiconductor package by resistance welding. According to this structure, the lower surface of the metal frame and the housing can be bonded to each other by heating only the bonded portions. Thus, the temperature of the glass member can be reduced below the softening point of the glass member when bonding the metal frame and the housing to each other, whereby the surface of the glass member is inhibited from softening by the temperature for bonding the metal frame and the housing to each other. Thus, the flatness and the parallelism of the glass member can be inhibited from reduction, whereby the light transmission properties of the glass member can be inhibited from reduction. Further, the temperature of a semiconductor device stored in the housing can be inhibited from increase when bonding the metal frame and the housing to each other, whereby the semiconductor device stored in the housing can be prevented from breakage resulting from temperature rise in the bonding between the metal frame and the housing.

A method of manufacturing a light transmission window member according to a third aspect of the present invention, which is a method of manufacturing a light transmission window member employed for a semiconductor package, comprises steps of preparing a flat metal frame having an opening for defining a light passage region and anodically bonding a glass member capable of transmitting light to the upper surface of the flat frame having the opening to cover the opening.

In the method of manufacturing a light transmission window member according to the third aspect of the present invention, as hereinabove described, the bonding temperature for the upper surface of the flat frame and the glass member can be reduced below the softening point of the glass temperature by anodically bonding the glass member to the upper surface of the flat frame, whereby the surface of the glass member is inhibited from softening by the temperature for bonding the flat frame and the glass member to each other. Thus, the flatness and the parallelism of the glass member can be inhibited from reduction, whereby the surface of the glass member may not be polished after the bonding between the upper surface of the flat frame and the glass member. Consequently, polishing can be performed in the single state of the glass member before the bonding between the glass member and the frame, whereby the glass member can be more easily polished as compared with a case of polishing the glass member bonded to the frame after the bonding between the glass member and the frame. Thus, the polishing step for the glass member can be simplified. Further, the glass member capable of transmitting light is bonded to the upper surface of the metal frame having the opening for defining the light passage region without through an adhesive, whereby the thickness of the frame may not be increased and no opening region for defining a light entrance region may be provided on the side of the glass member separately from the opening of the frame dissimilarly to a case of bonding the glass member to the inner side surface of the opening of the frame. Thus, the thickness of the frame can be reduced, and the structure of the light transmission window member can be simplified. In addition, no opening region for defining a light entrance region may be provided on the side of the glass member separately from the opening of the frame, whereby there is no need for a step of evaporating a shielding film of chromium or the like necessary in a case of providing an opening region on the glass member. Consequently, the manufacturing steps for the light transmission window member can be simplified.

In the aforementioned method of manufacturing a light transmission window member according to the third aspect, the anodic bonding step preferably includes a step of anodically bonding the flat metal frame having the opening defining the light transmission region and the glass member to each other through an Al layer. According to this structure, part (γ-alumina) of Al can be formed to extend in a comblike manner in the interface of the glass member when bonding the frame and the glass member to each other through the Al layer by anodic bonding, whereby the bond strength between the Al layer and the glass member can be increased. Thus, the bond strength between the metal frame and the glass member can be increased.

The aforementioned method of manufacturing a light transmission window member comprising the anodic bonding step including the step of anodically bonding the frame and the glass member to each other through the Al layer preferably further comprises a step of forming the Al layer on the bonded surface of the frame to the glass member in advance of the anodic bonding step. According to this structure, the frame and the glass member can be easily anodically bonded to each other through the Al layer.

The aforementioned method of manufacturing a light transmission window member according to the third aspect preferably further comprises a step of polishing the bonded surface of the glass member to the frame in advance of the anodic bonding step. According to this structure, the glass member can be easily polished in the single state.

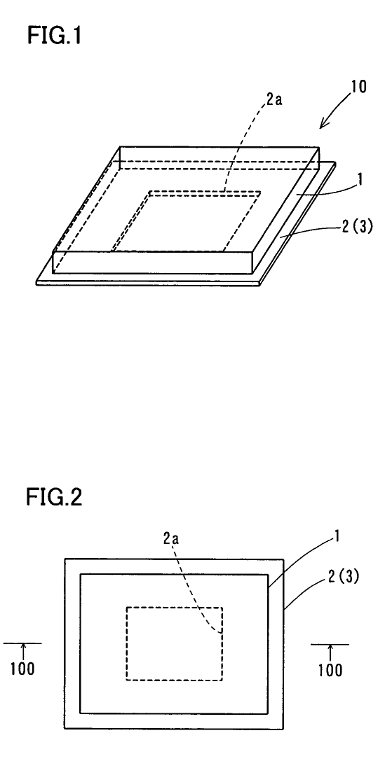

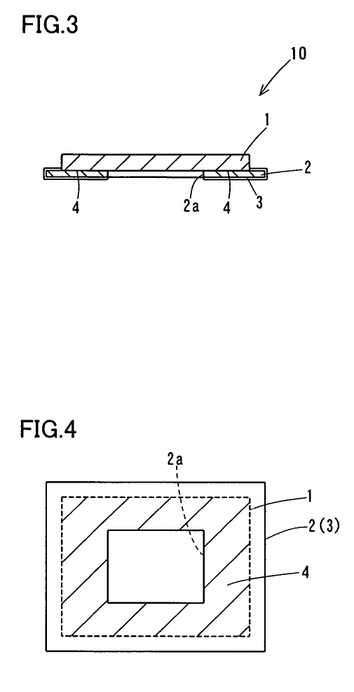

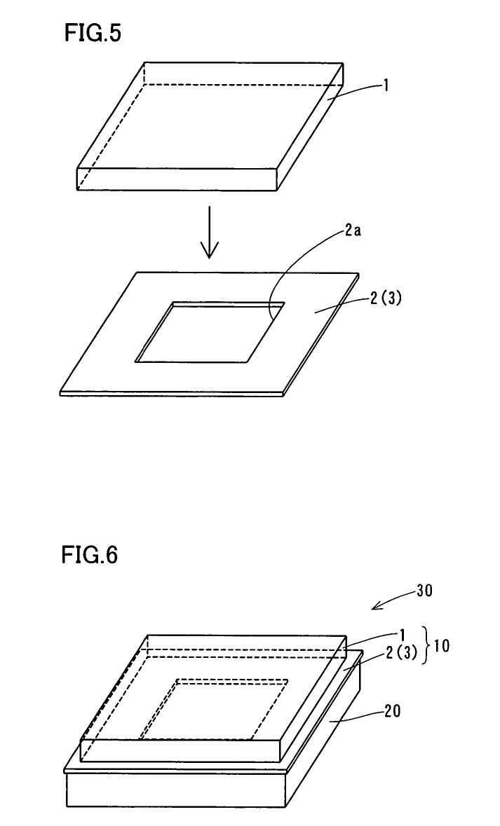

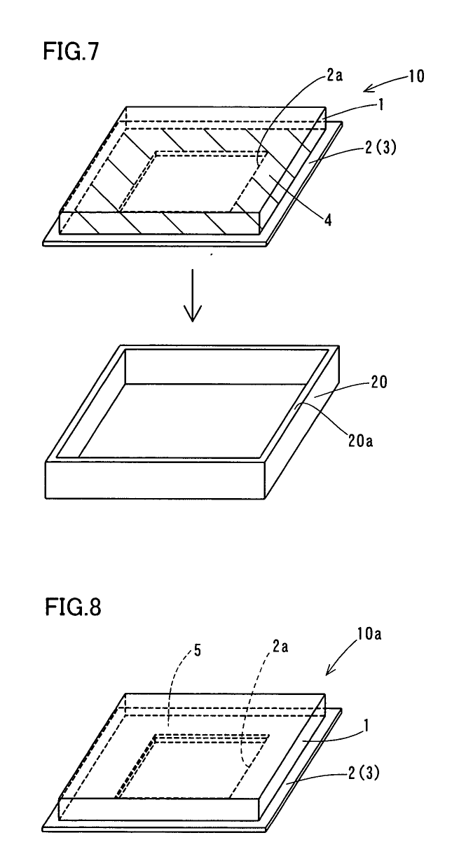

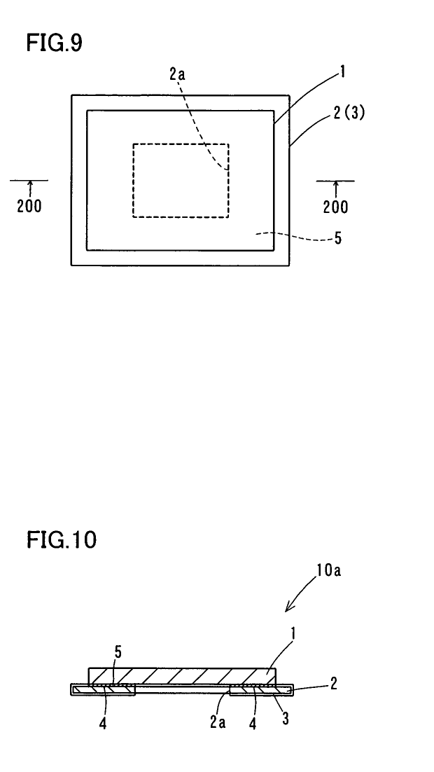

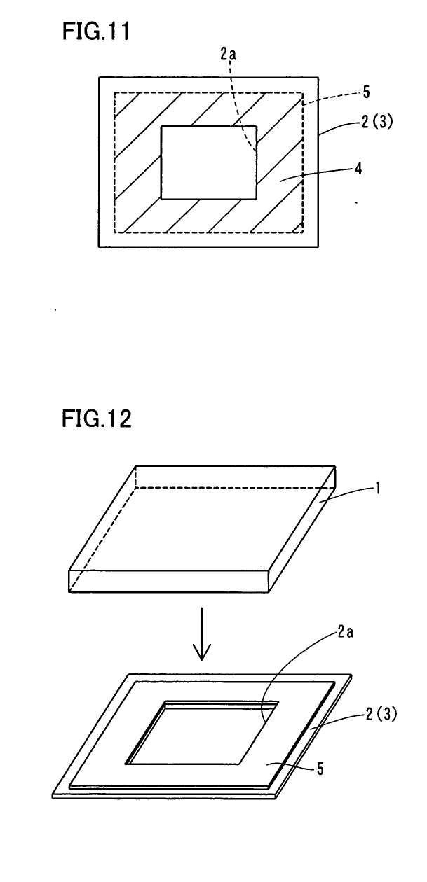

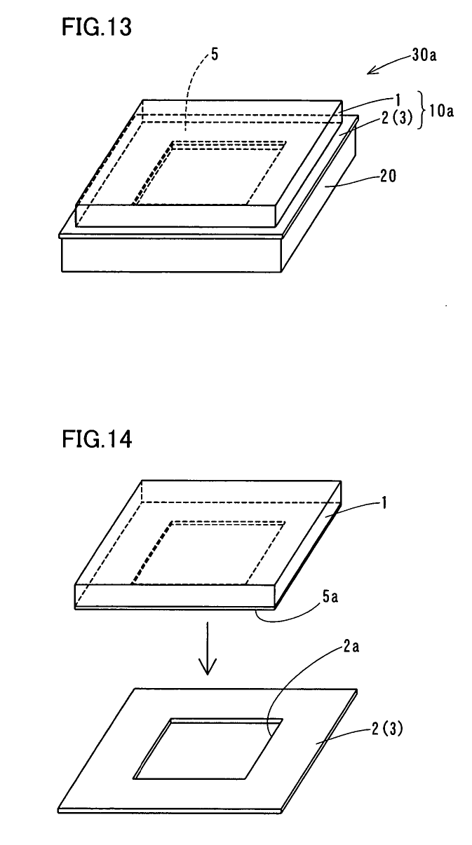

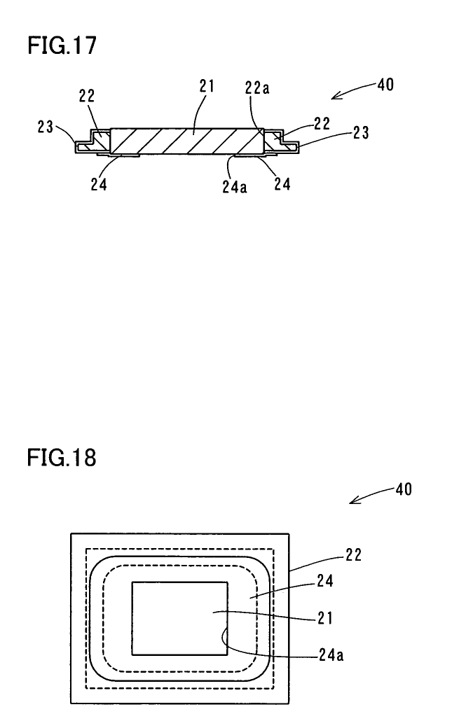

### BRIEF DESCRIPTION OF THE DRAWINGS

[FIG. 1] A perspective view showing the overall structure of a light transmission window member according to a first embodiment of the present invention.

[FIG. 2] A plan view showing the overall structure of the light transmission window member according to the first embodiment shown in FIG. 1.

[FIG. 3] A sectional view taken along the line 100-100 in FIG. 2.

[FIG. 4] A bottom plan view showing the overall structure of the light transmission window member according to the first embodiment shown in FIG. 1.

[FIG. 5] A perspective view for illustrating a manufacturing step for the light transmission window member according to the first embodiment shown in FIG. 1.

[FIG. 6] A perspective view showing the overall structure of a semiconductor package according to the first embodiment of the present invention.

[FIG. 7] A perspective view for illustrating a manufacturing step for the semiconductor package according to the first embodiment shown in FIG. 6.

[FIG. 8] A perspective view showing the overall structure of a light transmission window member according to a second embodiment of the present invention.

[FIG. 9] A plan view showing the overall structure of the light transmission window member according to the second embodiment shown in FIG. 8.

[FIG. 10] A sectional view taken along the line 200-200 in FIG. 9.

[FIG. 11] A bottom plan view showing the overall structure of the light transmission window member according to the second embodiment shown in FIG. 8.

[FIG. 12] A perspective view for illustrating a manufacturing step for the light transmission window member according to the second embodiment shown in FIG. 8.

[FIG. 13] A perspective view showing the overall structure of a semiconductor package according to the second embodiment of the present invention.

[FIG. 14] A perspective view for illustrating a light transmission window member according to a modification of the second embodiment of the present invention.

[FIG. 15] A perspective view showing the overall structure of a conventional light transmission window member.

[FIG. 16] A plan view showing the overall structure of the conventional light transmission window member shown in FIG. 15.

[FIG. 17] A sectional view taken along the line 300-300 in FIG. 16.

[FIG. 18] A bottom plan view showing the overall structure of the conventional light transmission window member shown in FIG. 15.

[FIG. 19] A perspective view for illustrating a manufacturing step for the conventional light transmission window member shown in FIG. 15.

[FIG. 20] A perspective view from a lower surface direction for illustrating the manufacturing step for the conventional light transmission window member shown in FIG. 15.

[FIG. 21] A perspective view showing the overall structure of a conventional semiconductor package.

[FIG. 22] A perspective view for illustrating a manufacturing step for the conventional semiconductor package shown in FIG. 21.

### BEST MODES FOR CARRYING OUT THE INVENTION

Embodiments of the present invention are now described with reference to the drawings.

### First Embodiment

FIGS. 1 to 4 are diagrams showing the overall structure of a light transmission window member according to a first embodiment of the present invention. FIG. 5 is a perspective view for illustrating a manufacturing step for the light transmission window member according to the first embodiment of the present invention. FIG. 6 is a perspective view showing the overall structure of a semiconductor package comprising the light transmission window member shown in FIG. 1, and FIG. 7 is a perspective view for illustrating a manufacturing step for the semiconductor package shown in FIG. 6. The structures of a light transmission window member 10 according to the first embodiment of the present invention and a semiconductor package 30 comprising the light transmission window 10 are first described with reference to FIGS. 1 to 4 and 6.

The light transmission window member 10 according to the first embodiment of the present invention comprises a glass member 1 capable of transmitting light, a frame 2 of KOVAR (iron-nickel-cobalt alloy (29Ni-16Co—Fe, for example)) and a gold plating layer 3, as shown in FIGS. 1 to 4.

The glass member 1 has an outer peripheral portion smaller than the outer peripheral portion of the frame 2, and has a thickness of at least about 3 mm. The glass member 1 contains alkaline ions of Na or the like. The glass member 1 has a thermal expansion coefficient of about 5.15×10⁻⁶/K to about 5.45×10⁻⁶/K. The glass member 1 has flatness of not more than about 2 μm and parallelism of not more than about 10 μm, while the lower surface (bonded surface) of the glass member 1 has surface roughness (Rmax) of not more than about 0.1 μm. This lower surface of the glass member 1 is anodically bonded to the upper surface of the flat frame 2 on a bond region 4 without through an adhesive. The frame 2 is formed in the shape of a flat plate having a small thickness of about 0.2 mm, and has an opening 2a for defining a light passage region on the central portion. The frame 2 of KOVAR (29Ni-16Co—Fe) has a thermal expansion coefficient of about 4.6×10⁻⁶/K to about 5.2×10⁻⁶/K. In other words, the frame 2 has the thermal expansion coefficient (about 4.6×10⁻⁶/K to about 5.2×10⁻⁶/K) in the vicinity of the thermal expansion coefficient (about 5.15×10⁻⁶/K to about 5.45×10⁻⁶/K) of the glass member 1. The upper surface (bonded surface) of the frame 2 is mirror-finished. The gold plating layer 3 is formed to cover all regions of the frame 2 excluding the bond region 4. This gold plating layer 3 is provided for preventing corrosion on the surface of the frame 2.

The light transmission window member 10 is bonded to a housing 20 of KOVAR (29Ni-16Co—Fe, for example) storing a DMD element (not shown) serving as a display device used for a projector, for example, by resistance welding to close the housing 20, as shown in FIG. 6. The light transmission window member 10 and the housing 20 constitute the semiconductor package 30 for the DMD element.

A manufacturing method for the light transmission window member 10 according to the first embodiment and a manufacturing method for the semiconductor package 30 comprising the light transmission window member 10 are now described with reference to FIGS. 1 and 5 to 7. First, the glass member 1 having the bonded surface (lower surface) of not more than about 0.1 μm in surface roughness (Rmax) and the glass member 1 having the flatness of not more than about 2 μm and the parallelism of not more than about 10 μm is formed by polishing the upper surface and the lower surface (bonded surface) of the glass member 1 capable of transmitting light, as shown in FIG. 5. Further, the opening 2a for defining the light passage region is formed in the flat frame 2 by press working, while the upper surface (bonded surface) of the frame 2 is mirror-finished. Then, the lower surface of the glass member 1 is anodically bonded to the upper surface of the frame 2 at a temperature of not more than the softening point of the glass member 1, to cover the opening 2a of the frame 2. Conditions for the anodic bonding in this case are a temperature of about 400° C. to about 500° C. and an applied voltage of at least about 500 V. The glass member 1 contains the alkaline ions of Na or the like, whereby the glass member 1 and the frame 2 of KOVAR can be easily anodically bonded to each other. After anodically bonding the glass member 1 and the frame 2 to each other, the gold plating layer 3 is formed by electrolytic plating to cover the overall outer surface of the frame 2. The light transmission window member 10 according to the first embodiment shown in FIG. 1 is formed in this manner.

The lower surface of the frame 2 of the light transmission window member 10 formed in the aforementioned manner is bonded to the upper surface 20a of the outer peripheral portion of the housing 20 storing the DMD element (not shown) by resistance welding to close the housing 20. Conditions for the bonding by resistance welding are a current of about 1000 A, a welding time of not more than about 5 msec. and a pressure of at least about 1 kg. Thus, the semiconductor package 30 for the DMD element consisting of the light transmission window member 10 and the housing 20 is formed as shown in FIG. 6.

According to the first embodiment, as hereinabove described, the glass member 1 capable of transmitting light is anodically bonded to the upper surface of the flat frame 2 of KOVAR having the opening 2a for defining the light passage region without through an adhesive, whereby the thickness of the frame 2 may not be increased and no opening region for defining a light entrance region may be provided on the glass member 1 separately from the opening 2a of the frame 2 dissimilarly to the case of bonding the glass member 21 to the inner side surface of the opening 22a of the conventional frame 22 shown in FIG. 17. Thus, the thickness of the frame 2 can be reduced, and the structure of the light transmission window member 10 can be simplified. Further, no opening region for defining a light entrance region may be provided on the glass member 1 separately from the opening 2a of the frame 2, whereby there is no need for a step of evaporating a shielding film of chromium or the like necessary in a case of providing an opening region on the glass member 1. Consequently, manufacturing steps for the light transmission window member 1 can be simplified.

According to the first embodiment, further, the glass member 1 is anodically bonded to the upper surface of the flat frame 2 so that the bonding temperature for the upper surface of the flat frame 2 and the glass member 1 can be reduced below the softening point of the glass member 1, whereby the surface of the glass member 1 is inhibited from softening by the temperature for bonding the flat frame 2 and the glass member 1 to each other. Thus, the flatness and the parallelism of the glass member 1 can be inhibited from reduction, whereby the surface of the glass member 1 may not be polished after the bonding between the upper surface of the flat frame 2 and the glass member 1. Consequently, polishing can be performed in the single state of the glass member 1 before the bonding between the glass member 1 and the frame 2, whereby the glass member 1 can be more easily polished as compared with a case of polishing the glass member 1 bonded to the frame 2 after the bonding between the glass member 1 and the frame 2. Thus, the polishing step for the glass member 1 can be simplified.

According to the first embodiment, further, the lower surface (bonded surface) of the glass member 1 is formed to have the surface roughness (Rmax) of not more than about 0.1 μm and the upper surface (bonded surface) of the flat frame 2 is mirror-finished so that formation of a clearance between the bonded surfaces of the upper surface of the flat frame 2 and the lower surface of the glass member 1 is suppressed, whereby air can be inhibited from passing through the bonded surfaces of the upper surface of the flat frame 2 and the lower surface of the glass member 1. Thus, when bonding the light transmission window member 10 having the frame 2 and the glass member 1 anodically bonded to each other to the housing 20 of the semiconductor package 30 by resistance welding, the housing 20 can be held in a closed state with the light transmission window member 10.

According to the first embodiment, the frame 2 of KOVAR is so formed as to have the thermal expansion coefficient in the vicinity of the thermal expansion coefficient of the glass member 1, whereby the glass member can be inhibited from warping or distortion resulting from difference between the thermal expansion coefficients of the frame 2 of KOVAR and the glass member 1 when the temperatures of the frame 2 of KOVAR and the glass member 1 lower to the ordinary temperature after the bonding.

According to the first embodiment, the lower surface of the frame 2 of KOVAR is bonded to the upper surface 20a of the outer peripheral portion of the housing 20 of KOVAR storing the DMD element (not shown) by resistance welding, so that the lower surface of the frame 2 and the housing 20 can be bonded to each other by local heating due to the resistance welding instantaneously feeding a current to welded portions for welding these portions by resistance heating thereof. Thus, the temperature of the glass member 1 can be reduced below the softening point of the glass member 1 when the frame 2 of KOVAR and the housing 20 are bonded to each other, whereby the surface of the glass member 1 is inhibited from softening by the temperature for bonding the frame 2 of KOVAR and the housing 20 to each other. Thus, the flatness and the parallelism of the glass member 1 can be inhibited from reduction, whereby the light transmission properties of the glass member 1 can be inhibited from reduction. Further, the temperature of the DMD element (not shown) stored in the housing 20 can be inhibited from increase when bonding the frame 2 of KOVAR and the housing 20 to each other, whereby the DMD element (not shown) stored in the housing 20 can be prevented from breakage resulting from temperature rise in the bonding between the frame 2 of KOVAR and the housing 20.

### Second Embodiment

FIGS. 8 to 11 are diagrams showing the overall structure of a light transmission window member according to a second embodiment of the present invention. FIG. 12 is a perspective view for illustrating a manufacturing step for the light transmission window member according to the second embodiment of the present invention. FIG. 13 is a perspective view showing the overall structure of a semiconductor package comprising the light transmission window member shown in FIG. 8. According to the second embodiment, a glass member 1 and a frame 2 of KOVAR are anodically bonded to each other through an Al layer 5, dissimilarly to the aforementioned first embodiment. The structures of a light transmission window member 10a according to the second embodiment of the present invention and a semiconductor package 30a comprising the light transmission window member 10a are now described with reference to FIGS. 8 to 11 and 13.

In the light transmission window member 10a according to the second embodiment of the present invention, the lower surface of the glass member 1 is anodically bonded to the upper surface of the flat frame 2 through the Al layer 5 on a bond region 4 (see FIGS. 10 and 11), as shown in FIGS. 8 to 11. This Al layer 5 has a thickness of about 0.05 μm to about 100 μm. If the thickness of the Al layer 5 is smaller than about 0.05 μm, the Al layer 5 may disappear due to diffusion of Al in the frame 2 of KOVAR. If the thickness of the Al layer 5 is larger than about 100 μm, on the other hand, the glass member 1 may be broken by tensile stress remaining in the glass member 1 due to difference between the thermal expansion coefficients of the Al layer 5 and the glass member 1. Therefore, the thickness of the Al layer 5 is preferably set to about 0.05 μm to about 100 μm. The Al layer 5 is formed only on the bond region 4 of the frame 2. As shown in FIG. 13, the light transmission window member 10a and a housing 20 constitute the semiconductor package 30a for a DMD element.

The remaining structure of the second embodiment is similar to that of the aforementioned first embodiment.

A manufacturing method for the light transmission window member 10a according to the second embodiment is now described with reference to FIGS. 8 and 12. First, the glass member 1 having a bonded surface (lower surface) of not more than about 0.1 μm in surface roughness (Rmax) as well as flatness of not more than about 2 μm and parallelism of not more than about 10 μm is formed by polishing the upper surface and the lower surface (bonded surface) of the glass member 1 capable of transmitting light, as shown in FIG. 12. An opening 2a for defining a light passage region is formed in the flat frame 2 by press working, while the upper surface (bonded surface) of the frame 2 is mirror-finished. Thereafter the Al layer 5 having the thickness of about 0.05 μm to about 100 μm is formed by evaporating Al to only the bond region 4 of the frame 2 through a mask. Since the upper surface of the frame 2 is mirror-finished, the upper surface of the Al layer 5 evaporated to the upper surface of the frame 2 is also formed as a mirror surface. The frame 2 and the Al layer 5 are diffusion-annealed at a temperature of about 400° C. to about 500° C. for about 1 minute. Then, the lower surface of the glass member 1 is anodically bonded to the upper surface of the Al layer 5 at a temperature of not more than the softening point of the glass member 1, to cover the opening 2a of the frame 2. Conditions for the anodic bonding in this case are a temperature of about 400° C. to about 500° C. and an applied voltage of at least about 500 V. At this time, part (γ-alumina) of the Al layer 5 is formed to extend in a comblike manner in the interface of the glass member 1. The glass member 1 contains alkaline ions of Na or the like, whereby the glass member 1 and the frame 2 of KOVAR can be easily anodically bonded to each other. After anodically bonding the glass member 1 and the frame 2 to each other through the Al layer 5, a gold plating layer 3 is formed by electrolytic plating to cover the overall outer surface of the frame 2. The light transmission window member 10a according to the second embodiment shown in FIG. 8 is formed in this manner.

A manufacturing method for the semiconductor package 30a (see FIG. 13) according to the second embodiment is similar to the manufacturing method for the aforementioned semiconductor package 30 according to the first embodiment.

According to the second embodiment, as hereinabove described, part (γ-alumina) of the Al layer 5 can be formed to extend in a comblike manner in the interface of the glass member 1 by anodically bonding the flat frame 2 of KOVAR and the glass member 1 to each other through the Al layer 5, whereby the bond strength between the Al layer 5 and the glass member 1 can be increased. Thus, the bond strength between the frame 2 of KOVAR and the glass member 1 can be increased.

The remaining effects of the second embodiment are similar to those of the aforementioned first embodiment.

The embodiments disclosed this time must be considered as illustrative in all points and not restrictive. The scope of the present invention is shown not by the above description of the embodiments but the scope of claim for patent, and all modifications within the meaning and the range equivalent to the scope of claim for patent are included.

For example, while each the aforementioned first and second embodiments has been described with reference to the light transmission window member employed for the semiconductor package for the DMD element, the present invention is not restricted to this but is also applicable to a light transmission window member employed for a semiconductor package for another semiconductor device other than the DMD element.

While the example of bonding the glass member to the frame by anodic bonding has been shown in each of the aforementioned first and second embodiments, the present invention is not restricted to this but a bonding method other than anodic bonding may alternatively be employed so far as the glass member and the frame can be bonded to each other without through an adhesive according to this method. As the bonding method other than anodic bonding in this case, it is preferable to employ a bonding method capable of bonding the glass member and the frame to each other at a temperature of not more than the softening point of glass without through an adhesive.

While the example of preparing the frame from KOVAR (iron-nickel-cobalt alloy) has been shown in each of the aforementioned first and second embodiments, the present invention is not restricted to this but the frame may alternatively be made of another metal. In this case, the frame is preferably made of a metal having a thermal expansion coefficient in the vicinity of the thermal expansion coefficient of the glass member. For example, an iron-nickel alloy such as 42Ni—Fe having a thermal expansion coefficient of about 4.5×10⁻⁶/K to about 5.3×10⁻⁶/K is conceivable as such a metal.

While the example of anodically bonding the frame and the glass member to each other through the Al layer has been shown in the aforementioned second embodiment, the present invention is not restricted to this but the frame and the glass member may alternatively be anodically bonded to each other through a metal layer other than the Al layer.

While the example of anodically bonding the frame and the glass member to each other through the Al layer after diffusion-annealing the frame and the glass member at the temperature of about 400° C. to about 500° C. for about 1 minute has been shown in the aforementioned second embodiment, the present invention is not restricted to this but the frame and the glass member may alternatively be anodically bonded to each other through the Al layer without diffusion-annealing the frame and the glass member. In this case, it is possible to diffusion-anneal the frame and the glass member while anodically bonding the same to each other.

While the example of evaporating Al to the bond region of the frame while anodically bonding the frame and the glass member to each other through the Al layer has been shown in the aforementioned second embodiment, the present invention is not restricted to this but a frame 2 and a glass member 1 may be anodically bonded to each other through an Al layer 5a while evaporating Al to the lower surface of the glass member 1, as in a modification of the second embodiment shown in FIG. 14.

While the example of evaporating Al to only the bond region of the frame through the mask has been shown in the aforementioned second embodiment, the present invention is not restricted to this but Al may alternatively be evaporated to the overall surface of the frame without a mask.

While the example of employing evaporation for forming the Al layer on the frame has been shown in the aforementioned second embodiment, the present invention is not restricted to this but the Al layer may alternatively be formed by a method such as plating or cladding, for example, other than evaporation for forming the Al layer on the frame. In other words, a clad material in which an Al layer is bonded to a frame consisting of a KOVAR layer may be formed by pressure-bonding the KOVAR layer for forming the frame and the Al layer to each other.

1. A light transmission window member (10, 10a) employed for a semiconductor package (30, 30a), comprising:
a flat metal frame (2) having an opening (2a) for defining a light passage region; and
a glass member (1) capable of transmitting light bonded to the upper surface of the flat frame having said opening without through an adhesive to cover said opening.

2. The light transmission window member according to claim 1, wherein the flat metal frame having the opening defining said light transmission region and said glass member are bonded to each other through an Al layer (5, 5a).

3. The light transmission window member according to claim 1 or 2, wherein said glass member is anodically bonded to the upper surface of the flat frame having the opening defining said light transmission region.

4. The light transmission window member according to claim 1 or 2, wherein said glass member is bonded to the upper surface of the flat frame having the opening defining said light transmission region at a temperature of not more than the softening point of said glass member.

5. The light transmission window member according to claim 1 or 2, wherein the upper surface of the flat frame having the opening defining said light transmission region, to which said glass member is bonded, is mirror-finished.

6. The light transmission window member according to claim 1 or 2, wherein the metal frame having the opening defining said light transmission region has a thermal expansion coefficient in the vicinity of the thermal expansion coefficient of said glass member.

7. The light transmission window member according to claim 6, wherein the frame having the opening defining said light transmission region consists of an iron-nickel-cobalt alloy.

8. The light transmission window member according to claim 1 or 2, wherein said glass member contains alkaline ions.

9. The light transmission window member according to claim 1 or 2, wherein the lower surface of said metal frame is bonded to a metal housing (20) of said semiconductor package to close said housing.

10. The light transmission window member according to claim 9, wherein the lower surface of said metal frame is bonded to the metal housing of said semiconductor package by resistance welding.

11. A semiconductor package (30, 30a) comprising a light transmission window member (10, 10a) including:
a flat metal frame (2) having an opening (2a) for defining a light passage region; and
a glass member (1) capable of transmitting light bonded to the upper surface of the flat frame having said opening without through an adhesive to cover said opening.

12. The semiconductor package according to claim 11, wherein the flat metal frame having the opening defining said light transmission region and said glass member are bonded to each other through an Al layer (5, 5a).

13. The semiconductor package according to claim 111 or 12, wherein said lass member is anodically bonded to the upper surface of said flat frame.

14. The semiconductor package according to claim 11 or 12, wherein said glass member is bonded to the upper surface of the flat frame having the opening defining said light transmission region at a temperature of not more than the softening point of said glass member.

15. The semiconductor package according to claim 11 or 12, further comprising a housing (20) bonded to the lower surface of said metal frame to be closed by the lower surface of said metal frame for storing a semiconductor device.

16. The semiconductor package according to claim 15, wherein said metal frame and said housing consist of the same material.

17. The semiconductor package according to claim 16, wherein said metal frame and said housing consist of an iron-nickel-cobalt alloy.

18. The semiconductor package according to claim 15, wherein the lower surface of said metal frame is bonded to the metal housing of said semiconductor package by resistance welding.

19. A method of manufacturing a light transmission window member (10, 10a) employed for a semiconductor package (30, 30a), comprising steps of:
preparing a flat metal frame (2) having an opening (2a) for defining a light passage region; and
anodically bonding a glass member (1) capable of transmitting light to the upper surface of the flat frame having said opening to cover said opening.

20. The method of manufacturing a light transmission window member according to claim 19, wherein said anodic bonding step includes a step of anodically bonding the flat metal frame having the opening defining said light transmission region and said glass member to each other through an Al layer (5, 5a).

21. The method of manufacturing a light transmission window member according to claim 20, further comprising a step of forming said Al layer on the bonded surface of said frame to said glass member,
in advance of said anodic bonding step.

22. The method of manufacturing a light transmission window member according to any of claims 19 to 21, further comprising a step of polishing the bonded surface of said glass member to said frame,
in advance of said anodic bonding step.
